(19) United States
(12) Patent Application Publication
(10) Pub. No.: US 2006/0081965 A1
(43) Pub. Date: Apr. 20, 2006

(54) Plasma treatment of an etch stop layer

(76) Inventors: Ju-Ai Ruan, Plano, TX (US); Qi-Zhong Hong, Richardson, TX (US); Zhijian Lu, Plano, TX (US)

Correspondence Address: TEXAS INSTRUMENTS INCORPORATED, P O BOX 655474, M/S 3999, DALLAS, TX, 75265, US

(21) Appl. No.: 10/966,506

(22) Filed: Oct. 15, 2004

(51) Int. Cl. H01L 23/58; H01L 21/42

(52) U.S. Cl. 257/632; 438/786; 438/798; 257/649

(57) ABSTRACT

A method of manufacturing an etch stop layer 18, 20, 21 on a semiconductor wafer 2 and the etch stop layer 18, 20, 21 produced by the method. The method includes depositing a dielectric layer 18, 20, 21 and applying a plasma treatment to the semiconductor wafer 2. Also, an etch stop layer 18, 20, 21 on a semiconductor wafer 2 having a modified surface and an amine deficient bulk.

### BACKGROUND OF THE INVENTION

This invention relates to a plasma treatment of etch stop dielectric material during the fabrication of semiconductor wafers.

### BRIEF DESCRIPTION OF THE DRAWINGS

FIG. 1 is a cross-section view of a semiconductor wafer in accordance with a first embodiment of the present invention.

FIG. 2 is a cross-section view of a semiconductor wafer in accordance with a second embodiment of the present invention.

FIG. 3 is a cross-sectional diagram of a process for manufacturing an etch stop layer in accordance with the present invention.

FIG. 4 is a cross-sectional diagram of a process for manufacturing an etch stop layer in accordance with a second embodiment of the present invention.

### DETAILED DESCRIPTION OF THE INVENTION

The present invention is described with reference to the attached figures, wherein like reference numerals are used throughout the figures to designate similar or equivalent elements. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

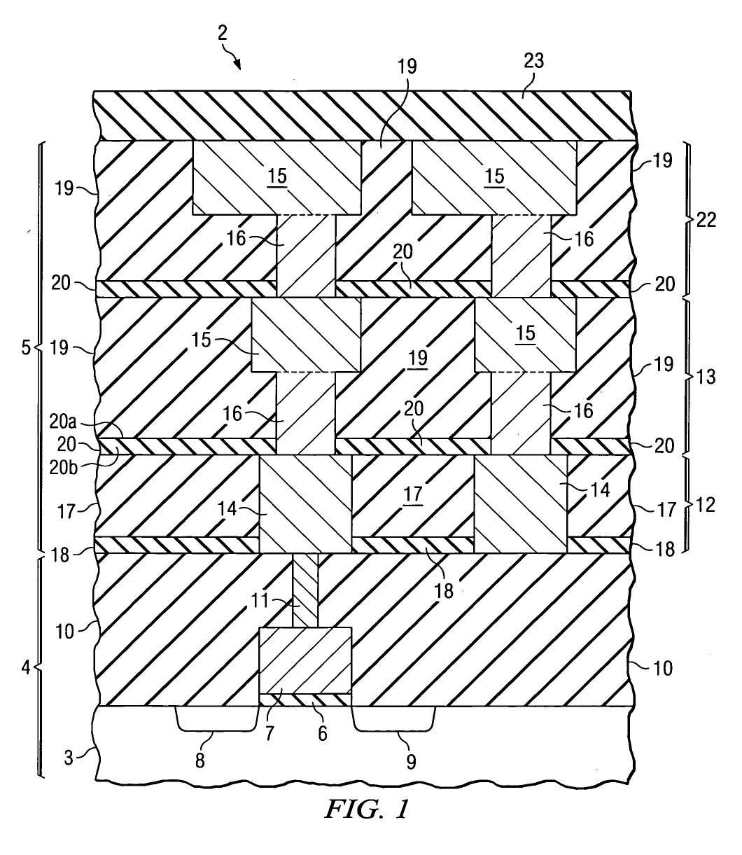

Referring to the drawings, FIG. 1 is a cross-section view of a semiconductor wafer 2 in accordance with a first embodiment of the present invention. Generally, the fabrication of an integrated circuit is divided into two parts: the fabrication of the Front-End-Of-Line (FEOL) structure 4 and the fabrication of the Back-End-Of-Line (BEOL) structure 5. The structure that includes the silicon substrate 3 is called the FEOL structure 4 of the integrated circuit. Normally, the FEOL 4 is the transistor layer formed on (and within) the semiconductor substrate 3. The semiconductor substrate 3 is preferably a doped single-crystal silicon substrate; however, other semiconductors such as GaAs and InP may be used. The partial FEOL 4 shown in FIG. 1 includes a transistor having a gate oxide 6, a gate electrode 7, and source/drain 8, 9; however, it is within the scope of the invention to have any form of logic within the FEOL structure 4.

Immediately above the transistor is a layer of dielectric insulation 10 containing metal contacts 11 that electrically tie the transistor to the other logic elements (not shown) of the FEOL structure 4. The dielectric insulation 10 may be comprised of any suitable materials such as SiO₂, organo-silicate glass (“OSG”), fluorinated silica glass (“FSG”), phosphate-doped silica glass (“PSG”), or any other suitable dielectric material. The contacts 11 are preferably comprised of W; however other conductive materials such as Cu, Ti, or Al may be used. An optional dielectric liner (not shown) may be formed before the dielectric insulation layer 10. If used, the dielectric liner may be any suitable material such as silicon nitride. Similarly, an optional contact liner (not shown) may be formed before the placement of the contacts 11 to reduce the contact resistance at the interface between the contact 11 and the active devices within the FEOL structure 4 (i.e. the gate electrode 11). If used, the contact liner may be any suitable material such as Ti, TiN, or Ta.

The example BEOL 5 contains a single damascene layer 12 and at least one dual damascene layer 13, 22. Layers 12, 13 and 22 contain metal lines 14, 15 that properly route electrical signals and power properly through the electronic device. Layers 13 and 22 also contain vias 16 that properly connect the metal lines of one metal layer (e.g. the metal lines 14 of layer 12) to the metal lines of another metal layer (e.g. the metal lines 15 of layer 13).

The single damascene layer 12 has metal lines 14 electrically insulated by dielectric material 17. The metal lines 14 may contain any conductive material such as Cu. However, the use of other materials such as Al, Ti, Ag, Sn, or Au is within the scope of this invention. In accordance with one embodiment of the invention, the dielectric material 17 is a low-k material such as OSG. However, the dielectric material 17 may also be FSG, SiO₂, any other low-k material, or any ultra low-k material. Furthermore, the single damascene layer 12 may have a thin dielectric layer 18 formed between the dielectric material 17 and the FEOL 4. Preferably, the dielectric layer 18 is comprised of SiCN; however, it is within the scope of this invention to use any suitable material for the thin dielectric layer 18. For example, the thin dielectric layer 18 may comprise SiC, SiCO, SION, or Si₃N₄.

The thin dielectric layer 18 may perform many functions. For example, dielectric layer 18 may function as a diffusion barrier layer by preventing the copper of interconnects 14 from diffusing to the silicon channel of the transistor or to another isolated metal line (thereby creating an electrical short). Second, thin dielectric layer 18 may function as an etch-stop when manufacturing the metal lines 14 within the dielectric insulation material 17. Lastly, the thin dielectric layer 18 may function as an adhesion layer to help hold a layer of OSG 17 to the FEOL 4. For purposes of readability, the thin dielectric layer 18 will be called the etch-stop layer 18 during the rest of the description of this invention.

Dual damascene layers 13 and 22 contain metal lines 15 and vias 16 that are electrically insulated by dielectric material 19. The metal lines 15 may contain any metal such as Cu. However, the use of other metals such as Al, Ti, Ag, Sn, or Au is within the scope of this invention. In accordance with one embodiment of the invention, the dielectric material 19 is a low-k material such as OSG. However, the dielectric material 19 may also be FSG, SiO₂, any other low-k material, or any ultra low-k material.

The dual damascene layers 13, 22 also contain a dielectric etch stop layer 20 that serves as a via etch-stop layer during manufacturing. Preferably, the etch stop layer 20 is SiCN, but any suitable dielectric material such as SiC, SiCO, SiON, or Si₃N₄ may be used as the etch-stop layer 20. An optional dielectric liner (not shown) may be formed between the etch stop layer 20 and the dielectric material 19. If used, the dielectric liner may be any suitable material such as tetraethyloxysilane (“TEOS”).

It is within the scope of the invention to fabricate an integrated circuit with one or more (or all) single damascene layers 12 and/or one or more dual damascene layers 13, 22. A protective overcoat 23 is usually formed over the last interconnect layer 22 to provide an oxygen and moisture barrier. Any suitable material may be used for the protective overcoat 23, such as SiO₂ or SiN.

In accordance with the present invention, a BEOL interconnect layer 12, 13, or 22 is manufactured with a process that reduces—and possibly prevents—photoresist poisoning. This is accomplished by performing a plasma treatment (described more fully below) to the semiconductor wafer 2 following the deposition of an etch stop layer 20.

The plasma treatment of the present invention will change both the surface 20a and the bulk (body) 20b of the treated etch stop layer 20. More specifically, the plasma treatment will make the surface 20a of the etch stop layer more amine and oxygen deficient, more carbon rich, and denser than the surface 20a would be without the plasma treatment. Furthermore, the bulk 20b of the etch stop layer will be more amine deficient. The amine species created by current BEOL manufacturing processes is a nitrogen containing amine such as NH₃ and NH₂.

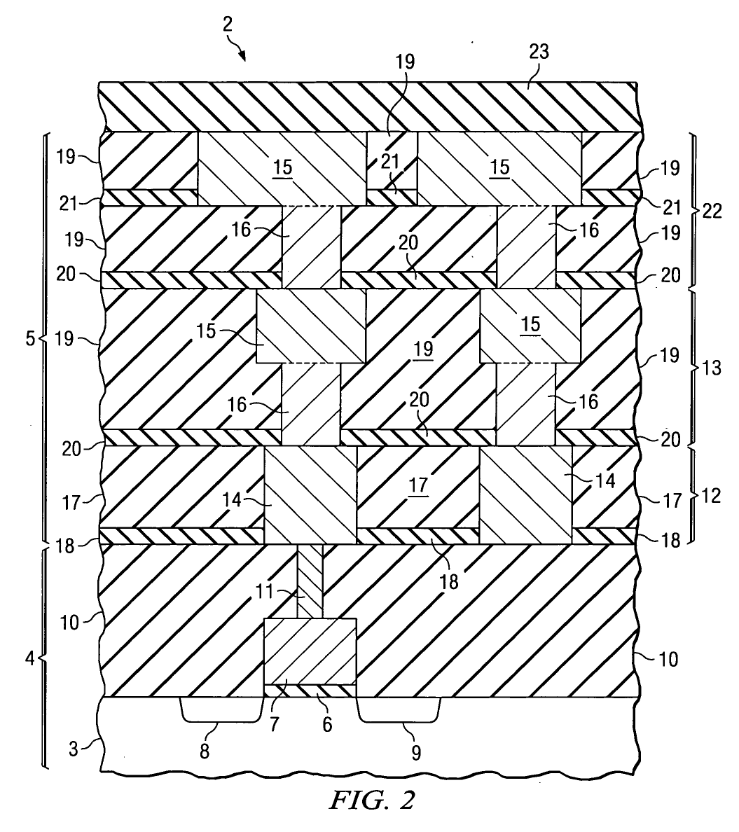

It is within the scope of the invention to perform the plasma treatment process of the present invention on one or more via etch stop layers 18, 20 (e.g. the plasma treatment process may be performed on either a single damascene layer 12 or a dual damascene layer 13, 22). In addition, the plasma treatment process may be performed on one or more trench etch stop layers 21, as shown in FIG. 2. In the example application, the plasma treatment process is not performed after the deposition of the first etch stop layer (i.e. etch stop layer 18 of the BEOL layer 12), yet it is performed after the deposition of every etch stop layer thereafter. The plasma treatment process is not performed after the deposition of the first etch stop layer (i.e. layer 18) in the example application because photoresist poisoning is generally not an issue in the first BEOL layer 12 (i.e. the FEOL 4 doesn't contain amines). However, if photoresist poisoning is an issue in the first BEOL layer 12, then the plasma treatment of the present invention may also be performed on etch stop layer 18.

It is to be noted that the plasma treatment process of the present invention will also reduce or prevent photoresist poisoning during photoresist rework processes. A rework process is a re-patterning process that is done when a previous photoresist patterning process was unsatisfactory (i.e. trench and via pattern misalignment).

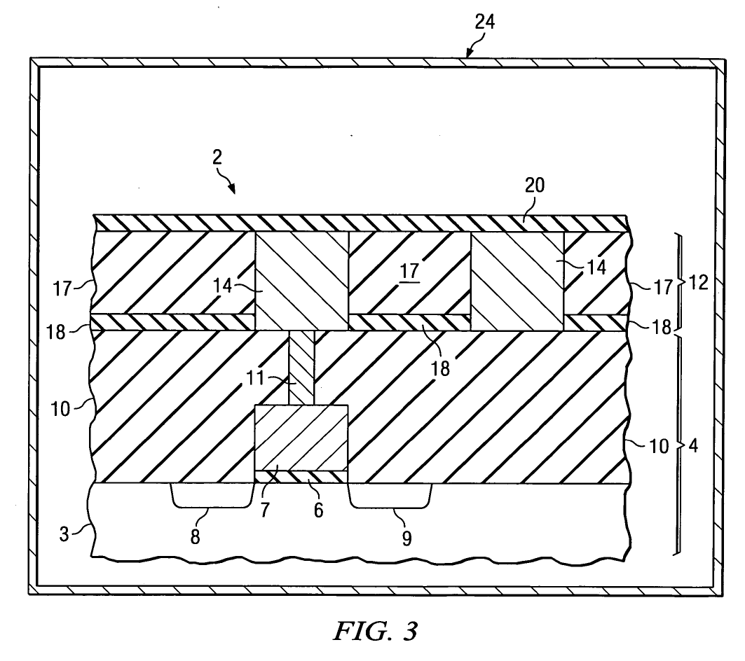

FIG. 3 is cross-sectional diagram of a process for manufacturing an etch stop layer in accordance with the best mode of the present invention. Because the present invention may be used with any integrated circuit configuration, standard manufacturing processes are used to fabricate the front-end structure 4 to create any logic elements necessary to perform the desired integrated circuit function. In addition, the single damascene layer 12 of the BEOL 5 is fabricated over the FEOL 4 using current manufacturing processes.

As noted above, the plasma treatment is not applied to the etch stop 18 of the first interconnect layer 12 of the BEOL structure 5 in the best mode application; however, the plasma treatment is applied to every interconnect layer 13, 22 of the BEOL 5 except the first interconnect layer 12.

Referring again to FIG. 3, a via etch-stop layer 20 is now formed over the entire semiconductor wafer 2. The via etch-stop layer 20 may be formed with any suitable manufacturing process such as Plasma-Enhanced Chemical Vapor Deposition (“PECVD”) using any suitable deposition machine (such as the Producer made by Applied Materials). In this example application, the via etch-stop layer 20 is comprised of SiCN; however, other dielectric materials such as SiC, SiCO₂, SiON, or Si₃N₄ may be used.

In accordance with the best mode of the present invention, the deposition chamber 24 used for the fabrication of the via etch stop layer 20 is now purged. During the purging process, the NH₃ gas that flowed into the deposition chamber 24 during the deposition of the via etch stop layer 20 is turned off. In addition, the He gas that flowed during the deposition of the via etch stop layer 20 continues to flow. In fact, the He gas comprises 100% of the gas that is flowing during the purge step. Moreover, the pump that was applied during the deposition of the via etch stop layer 20 continues to remove gases from the deposition chamber 24. The deposition chamber is purged for over 10 seconds—but preferably for 35-45 seconds—in order to remove all (or almost all) of the ammonia gas from the deposition chamber 24.

It is within the scope of the invention to omit the purge process just described. Furthermore, it is within the scope of the invention to use other suitable gases or gas mixtures for the purge process (just described) and the plasma treatment (described below). For example, gases or gas mixtures such as Ar or CO₂ may be used instead of He.

In the best mode application, the next step is the plasma treatment of the semiconductor wafer 2. Moreover, in the best mode application the plasma treatment is performed in the same deposition chamber 24 that has just been purged. However, it is within the scope of the invention to perform the plasma treatment in an adjoining chamber without breaking vacuum, or to perform the plasma treatment in a different chamber after breaking vacuum (i.e. by removing the wafer and placing it into a different deposition chamber for the plasma treatment). The plasma treatment process may even be performed in the deposition chamber used for the next manufacturing step (i.e. the chamber used to deposit the dielectric layer 19).

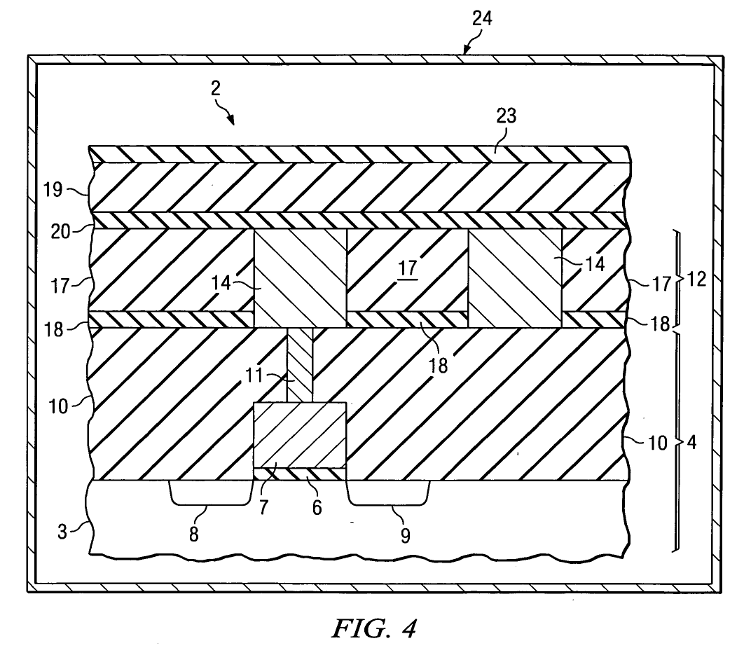

The plasma treatment is performed by striking a plasma with the He gas flowing into the deposition chamber 24. The plasma treatment is performed for more than 2 seconds; preferably for 3-9 seconds. Once the plasma treatment process is complete the fabrication of the semiconductor wafer 2 continues, using standard manufacturing processes. However, in the best mode application the purge and plasma treatment processes are performed after the formation of every etch stop layer 20, 21. For example, as shown in FIG. 4 the purge and plasma treatment processes would be performed after the deposition of the next etch stop layer (i.e. after the deposition of the trench etch stop layer 21).

Various modifications to the invention as described above are within the scope of the claimed invention. As an example, the plasma treatment process of the present invention may be performed on the etch stop of a single damascene layer 12. Also, the methods of the present invention may be performed after the deposition of the first etch stop layer 18. Furthermore, the present invention may be used on every etch stop layer 18, 20, 21 of the BEOL 5.

In addition, it is within the scope of the invention to have a BEOL structure 5 with a different amount or configuration of metal layers 12, 13, 22 than is shown in FIGS. 1 and 2. Moreover, the dual damascene layers 13, 22 may be fabricated with either the via-first or trench-first process. The interconnect structures 12, 13, 22 may contain more layers, such as a layer of TEOS between the dielectric 17, 19 and the adjoining etch stop layer 20, 21. Furthermore, the semiconductor substrate 3 may include various elements therein and/or layers thereon. These can include metal layers, barrier layers, dielectric layers, device structures, active elements and passive elements including word lines, source regions, drain regions, bit lines, bases, emitters, collectors, conductive lines, conductive vias, etc. Moreover, instead of using the invention on a CMOS structure as described above, the invention is applicable to other semiconductor technologies such as BiCMOS, bipolar, SOI, strained silicon, pyroelectric sensors, opto-electronic devices, microelectrical mechanical system (“MEMS”), or SiGe.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A method of manufacturing an etch stop layer on semiconductor wafer comprising:
depositing a dielectric layer over said semiconductor wafer; and
applying a plasma treatment to said semiconductor wafer.

2. The method of claim 1 wherein said plasma treatment step is performed by applying plasma to said semiconductor wafer for more than 2 seconds.

3. The method of claim 1 wherein said plasma treatment step is performed by applying a He plasma to said semiconductor wafer.

4. The method of claim 1 wherein said plasma treatment step is performed in-situ.

5. The method of claim 1 wherein said plasma treatment step is performed in-situ in a different deposition chamber than the deposition chamber used to perform the deposition step.

6. The method of claim 1 wherein said plasma treatment step is performed ex-situ.

7. The method of claim 1 wherein said dielectric layer comprises SiCN.

8. The method of claim 1 wherein said etch stop layer is located in a single damascene layer of said semiconductor wafer.

9. The method of claim 1 wherein said etch stop layer is located in a dual damascene layer of said semiconductor wafer.

10. The method of claim 1 wherein said etch stop layer is a via etch stop layer.

11. The method of claim 1 wherein said etch stop layer is a trench etch stop layer.

12. The method of claim 1 further comprising a step of purging a deposition chamber containing said semiconductor wafer prior to said plasma treatment step.

13. The method of claim 12 wherein said purging step is performed for more than 10 seconds.

14. The method of claim 12 wherein said purging step is performed by pumping said deposition chamber and purging said deposition chamber with He gas.

15. An etch stop layer of a semiconductor wafer produced by the method of claim 1.

16. An etch stop layer of a semiconductor wafer produced by the method of claim 12.

17. An etch stop layer on semiconductor wafer comprising a dielectric layer having a modified surface and an amine deficient bulk.

18. The etch stop layer of claim 17 wherein said surface is also oxygen deficient.

19. The etch stop layer of claim 17 wherein said surface is also carbon rich.

20. The etch stop layer of claim 17 wherein said surface is also amine deficient.

21. The etch stop layer of claim 17 wherein said amines are nitrogen containing amines.
